(19) United States
(12) Patent Application Publication
(10) Pub. No.: US 2011/0045650 A1
(43) Pub. Date: Feb. 24, 2011

(54) Method of manufacturing semiconductor device

(75) Inventor: Atsushi Maekawa, Tokyo (JP)

Correspondence Address: YOUNG & THOMPSON, 209 Madison Street, Suite 500, Alexandria, VA, 22314, US

(73) Assignee: Elpida Memory, Inc., Tokyo (JP)

(21) Appl. No.: 12/805,779

(22) Filed: Aug. 19, 2010

(30) Foreign Application Priority Data
Aug. 20, 2009 (JP) 2009-190955

(51) Int. Cl. H01L 21/02

(52) U.S. Cl. 438/396; 257/E21.008

(57) ABSTRACT

A method of manufacturing a semiconductor device may include, but is not limited to the following processes. First and second electrodes are formed in a first insulating film over a semiconductor substrate. The first and second electrodes upwardly extend from the semiconductor substrate. The first and second electrodes have first and second upper portions protruding from an upper surface of the first insulating film, respectively. A support film, which covers the upper surface of the first insulating film and the first and second upper portions, is formed. The support film is patterned so that a remaining portion of the support film connects the first and second upper portions. The first insulating film is removed while the remaining portion mechanically supports the first and second electrodes.

### BACKGROUND OF THE INVENTION

1. Field of the Invention

The present invention relates to a method of manufacturing a semiconductor device. Particularly, the present invention relates to a method of manufacturing a semiconductor device in which a bridge portion made of amorphous carbon is formed, and then a capacitor is formed by a wet etching process.

Priority is claimed on Japanese Patent Application No. 2009-190955, filed Aug. 20, 2009, the content of which is incorporated herein by reference.

2. Description of the Related Art

Recently, DRAM (Dynamic Random Access Memory) memory cells have been miniaturized with miniaturization of semiconductor devices. Regarding a DRAM memory cell, a crown-shaped (cylindrical) lower electrode of a capacitor is formed so as to increase the area of a side surface of the lower electrode, thereby maintaining sufficient capacitance.

However, a bottom surface of the crown-shaped (cylindrical) lower electrode is smaller in area than the side surface thereof, and therefore the lower electrode is unstable. For this reason, when an inter-layer insulating film, such as a silicon oxide (SiO₂) film, is wet-etched using an etching solution mainly containing HF (hydrofluoric acid) in a capacitor formation process, in order to expose an outer side surface of the lower electrode, the lower electrode is likely to fall. Therefore, adjacent lower electrodes are likely to short-circuit.

To prevent a lower electrode from falling, a technique of forming a bridge portion, which is made of SiN and the like and connects adjacent lower electrodes, has been developed.

Japanese Patent Laid-Open Publication No. 2003-142605 discloses a beam for preventing a cylindrical capacitor from falling. Specifically, a material, such as SiN, is used as the beam. However, another material may be used as long as the material has different etching characteristics from that of a sacrificial insulating film.

Japanese Patent Laid-Open Publication No. 2003-297952 discloses a support layer that mechanically supports adjacent lower electrodes in order to prevent a cylindrical capacitor from falling. The support layer is made of a material, such as SiN, which has a different etching selectivity from that of another oxide film.

Japanese Patent Laid-Open Publication No. 2006-135261 discloses a supporting base layer that is made of amorphous carbon and is a basis for forming a lower electrode. Although the supporting base layer is not a beam, the supporting base layer can prevent the lower electrode from falling and can be removed by a dry etching process.

In related arts, a crown-shaped (cylindrical) capacitor is formed by processes shown in FIGS. 17 to 21. Firstly, a first inter-layer insulating film 2 is formed over a semiconductor substrate 1, as shown in FIG. 17. Then, a second inter-layer insulating film 3 is formed over the first inter-layer insulating film 2. Then, a through hole is formed so as to penetrate the second inter-layer insulating film 3. Then, a contact 4 is formed so as to fill the through hole. Then, a pad 5 is formed over the second inter-layer insulating film 3 so as to be connected to the contact 4.

Then, a third insulating film (stopper film) 6 is formed so as to cover the pad 5. Then, a fourth inter-layer insulating film 7, made of a silicon oxide film, is formed over the stopper film 6. Then, a groove pattern is formed in the fourth inter-layer insulating film 7. The groove pattern is adjacent to an upper surface 7c of the fourth inter-layer insulating film 7. Then, a silicon nitride film is formed so as to fill the groove pattern. The silicon nitride film forms the support film 8 that will be the bridge portion.

Then, a resist film is formed over the upper surface 7c of the fourth inter-layer insulating film 7 and then is processed by a photolithography process to form a resist mask 13, as shown in FIG. 18. Then, the fourth inter-layer insulating film 7 and the stopper film 6 are dry-etched using the resist mask 13 until a part of the pad 5 is exposed, and thus the hole 7a is formed, as shown in FIG. 19.

After the resist mask 13 is removed, a multi-layered structure, which includes, for example, a titanium nitride film and a titanium film, is formed so as to cover an inner surface of the hole 7a and the upper surface 7c of the fourth inter-layer insulating film 7. Then, only a portion of the multi-layered structure, which covers the upper surface 7a of the fourth inter-layer insulating film 7, is removed by a photolithography process and a dry etching process. Thus, a remaining portion of the multi-layered structure, which covers the inner surface of the hole 7a, forms the lower electrode 9, as shown in FIG. 20.

Then, the fourth inter-layer insulating film 7 is removed by a wet-etching process, as shown in FIG. 21. Consequently, an outer surface of the lower electrode 9, which is mechanically supported by the support film 8, is exposed. At the same time, the support film 8 is etched from both upper and lower surfaces thereof using the wet etching with low etching selectivity. Therefore, a thickness of the support film 8 is reduced, thereby causing a decrease in supporting strength of the support film 8. In this case, adjacent lower electrodes gravitate toward each other due to surface tension of the etching solution during the wet etching process, thereby causing the lower electrodes 9 to be likely to fall.

To prevent the above problem, a thicker support film 8 has been formed to achieve sufficient supporting strength of the support film 8 even after the wet etching process. However, if a thicker support film 8 is formed, the selectivity of the support film 8 to the resist mask 13 has to be lowered, thereby making it difficult to maintain the size and the shape of the hole 7a. In other words, a variation in size of the hole 7a and a deformation of the hole 7a occur, thereby making it difficult to form lower electrodes in uniform size and shape.

### SUMMARY

In one embodiment, a method of manufacturing a semiconductor device may include, but is not limited to the following processes. First and second electrodes are formed in a first insulating film over a semiconductor substrate. The first and second electrodes upwardly extend from the semiconductor substrate. The first and second electrodes have first and second upper portions protruding from an upper surface of the first insulating film, respectively. A support film, which covers the upper surface of the first insulating film and the first and second upper portions, is formed. The support film is patterned so that a remaining portion of the support film connects the first and second upper portions. The first insulating film is removed while the remaining portion mechanically supports the first and second electrodes.

In another embodiment, a method of manufacturing a semiconductor device may include, but is not limited to the following processes. First and second electrodes are formed in an insulating film over a semiconductor substrate. The first and second electrodes upwardly extend from the semiconductor substrate. The first and second electrodes have first and second upper portions protruding from an upper surface of the insulating film. A support film, which covers the upper surface of the insulating film and the first and second upper portions, is formed. A mask is formed over the support film. The mask overlaps at least partially the first and second electrodes in plan view. The support film is patterned using the mask so that a remaining portion of the support film connects the first and second upper portions. The insulating film is removed while the remaining portion mechanically supports the first and second electrodes.

In still another embodiment, a method of manufacturing a semiconductor device may include, but is not limited to the following processes. First and second holes are formed in the insulating film. First and second electrodes, which cover first and second inner surfaces of the first and second holes, respectively, are formed. The insulating film is selectively etched so that first and second upper portions of the first and second electrodes protrude from an etched upper surface of the insulating film. A support film is formed. The support film comprises first to third portions. The first portion covers the etched upper surface. The second and third portions fill upper spaces of the first and second holes covered by the first and second electrodes. The second and third portions are removed so that the first portion connects the first and second upper portions. The insulating film is removed while the first portion mechanically supports the first and second electrodes.

### BRIEF DESCRIPTION OF THE DRAWINGS

The above features and advantages of the present invention will be more apparent from the following description of certain preferred embodiments taken in conjunction with the accompanying drawings, in which:

FIGS. 1-3, 4B, 5, 6, 7B, 8B, 9, and 10 are cross-sectional views indicative of a process flow illustrating a method of manufacturing a semiconductor device according to a first embodiment of the present invention, in which FIGS. 4B, 7B, and 8B are cross-sectional views taken along lines A-A′, B-B′, and C-C′ shown in FIGS. 4A, 7A, and 8A that are plan views;

FIG. 11 is a cross-sectional view illustrating a process included in a method of manufacturing a semiconductor device according to a second embodiment of the present invention;

FIGS. 12 to 16 are cross-sectional views indicative of a process flow illustrating a method of manufacturing semiconductor devices according to comparative examples of the present invention; and

FIGS. 17 to 21 are cross-sectional views indicative of a process flow illustrating a method of manufacturing a semiconductor device according to a related art.

### DETAILED DESCRIPTION OF THE PREFERRED EMBODIMENTS

The present invention will now be described herein with reference to illustrative embodiments. The accompanying drawings explain a method of manufacturing a semiconductor device in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

### First Embodiment

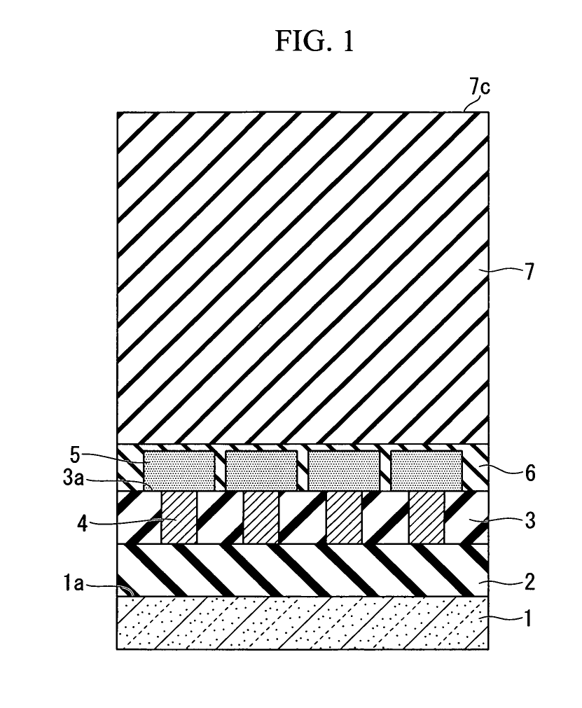

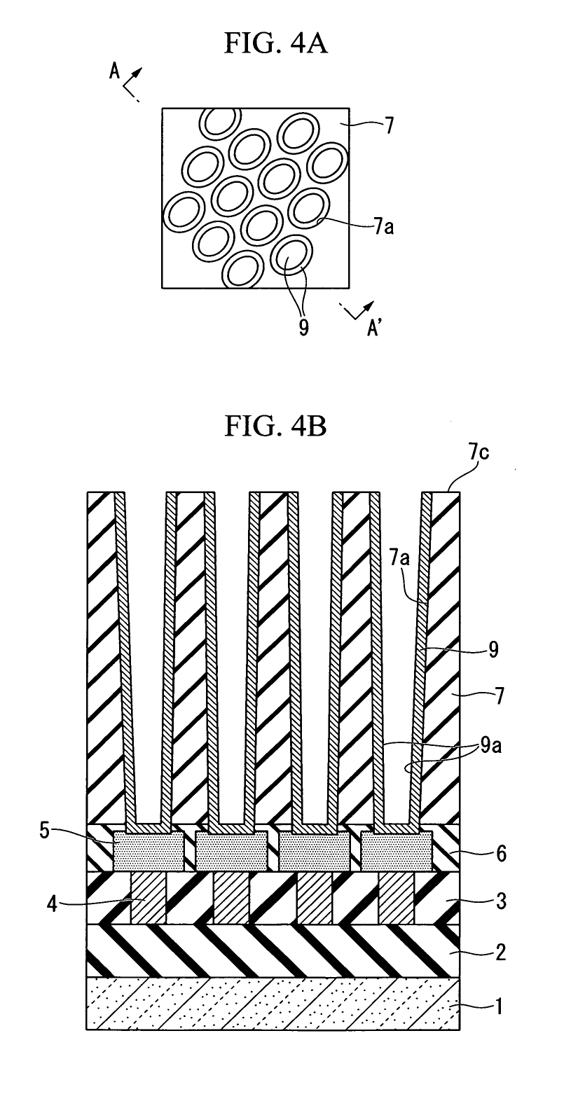

Hereinafter, a method of manufacturing a semiconductor device according to a first embodiment of the present invention is explained with reference to FIGS. 1 to 10. FIGS. 1-3, 4B, 5, 6, 7B, 8B, 9, and 10 are cross-sectional views indicative of a process flow illustrating the method of the first embodiment. FIGS. 4A, 7A, and 8A are plan views. FIGS. 4B, 7B, and 8B are cross-sectional views taken along lines A-A′, B-B′, and C-C′ shown in FIGS. 4A, 7A, and 8A, respectively.

As shown in FIG. 1, a first insulating film 2, made of a silicon oxide film and the like, is formed over an upper surface 1a of a semiconductor substrate (hereinafter, “substrate”) 1 made of silicon. Although not shown in FIG. 1, an isolation region and a diffusion region are formed in the substrate 1 on the side of the surface 1a. Additionally, a transistor, a wire, and the like are formed in the first insulating film 2.

Then, a second insulating film 3, made of a silicon oxide film, is formed over the first insulating film 2. Then, a contact hole is formed in the second insulating film 3. Then, a conductive material is provided to fill the contact hole, and thus a contact 4 is formed. Then, a pad 5 is formed on an upper surface 3a of the second insulating film 3 so as to be connected to the contact 4. The pad 5 is made of a metal, such as tungsten (W), or of poly-silicon (p-Si). The contact 4 electrically connects, to the pad 5, the transistor, and the wire, and the like, which are formed in the first insulating film 2.

Then, a third insulating film 6 is formed by using low-pressure CVD (Chemical Vapor Deposition) and the like, so as to cover the second insulating film 3 and the pad 5. The third insulating film 6 prevents a wet etching solution from penetrating into the underlying layers, and thereby is called a stopper film. The third insulating film 6 includes, for example, a silicon nitride film. A thickness of the third insulating film 6 is, for example, 50 nm.

Then, a fourth insulating film 7 is formed over the third insulating film 6. The fourth insulating film 7 includes, for example, a multi-layered film including a BPSG (Boron Phosphorus Silicate Glass) film and a silicon oxide film. A thickness of the fourth insulating film 7 is, for example, 2.2 μm. The BPSG film is formed by using normal-pressure CVD and the like. The silicon oxide film is formed by using plasma CVD and the like.

Then, the thickness of the fourth insulating film 7 is reduced from the upper surface 7a thereof by approximately 200 nm by using CMP (Chemical Mechanical Polishing). Thus, the upper surface 7c of the fourth insulating film 7 is planarized.

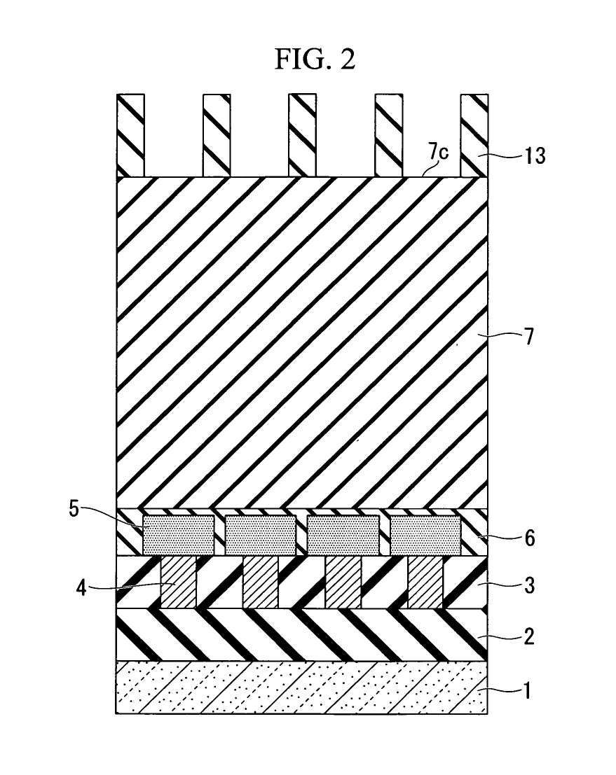

Then, a resist film is formed over the fourth insulting film 7, and then a resist mask 13 is formed over the fourth insulating film 7 by using photolithography, as shown in FIG. 2. The resist mask 13 partially covers the upper surface 7c of the fourth insulating film 7 such that the upper surface 7c of the fourth insulating film 7 is partially exposed.

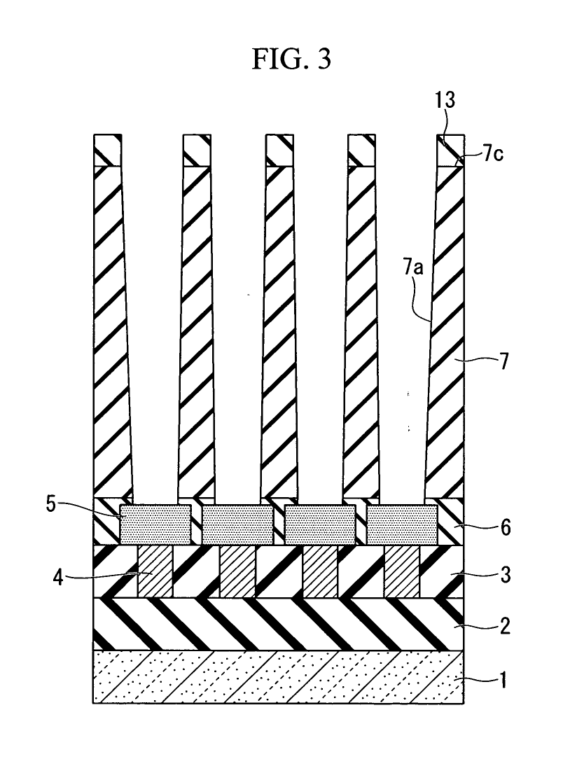

Then, the fourth insulating film 7 and the third insulating film 6 are dry-etched using the resist mask 13 until a part of the pad 5 is exposed. Thus, a hole 7a is formed such that a part of the pad 5 is exposed to the hole 7a, as shown in FIG. 3. The dry etching is carried out using parallel plate RIE (Reactive Ion Etching), at a source power of 1500 W, at a pressure of 20 mTorr, at a wafer temperature of 20° C., with a process gas containing C₄F₆ (hexafluoro-1,3-butadiene), CHF₃ (trifluoromethane), O₂ (oxygen), Ar (argon) at a flow rate of C₄F₆/CHF₃/O₂/Ar=30/30/25/400 sccm.

A diameter of the hole 7a is smaller as the level of the hole 7a is lower, as shown in FIG. 3. The diameter of the hole 7a at the level of the upper surface of the resist mask 13 is, for example, 85 nm. A depth of the hole 7a is, for example, 2.0 μm. Each hole 7a has a uniform shape. There is no variation in diameter and depth of each hole 7a.

Then, the resist mask 13 is removed. Then, a multi-layered structure including a titanium nitride film and a titanium film is formed in a thickness of, for example, 25 nm so as to cover an inner surface of the hole 7a and the upper surface 7c of the fourth insulating film 7. Then, only a portion of the multi-layered structure, which covers the upper surface 7c of the fourth insulating film 7, is removed by using photolithography and dry etching. Thus, a remaining portion of the multi-layered structure, which covers the inner surface of the hole 7a, forms an lower electrode 9, as shown in FIGS. 4A and 4B.

As shown in FIG. 4A, multiple holes 7a, which are elliptical in plan view, are formed in a matrix. The lower electrode 9 covers the inner surface of the hole 7a. As shown in FIG. 4B, the lower electrode 9 covers the inner and bottom surfaces of the hole 7a. The bottom surface of the lower electrode 9 is in contact with the contact pad 5. The inner surface of the lower electrode 9 is exposed.

Then, a thickness of the fourth insulating film 7 is uniformly reduced from the surface 7c thereof by approximately 50 nm by using, for example, wet etching. The wet etching is carried out by using a buffer hydrofluoric acid solution at a composition ratio of HF (hydrofluoric acid):NH₄F (ammonium fluoride)=0.1 wt %:20 wt %, at a solution temperature of 20° C., at an etching rate of a silicon oxide film (when plasma CVD is used) of 10 nm/min, for a processing time of approximately 5 seconds.

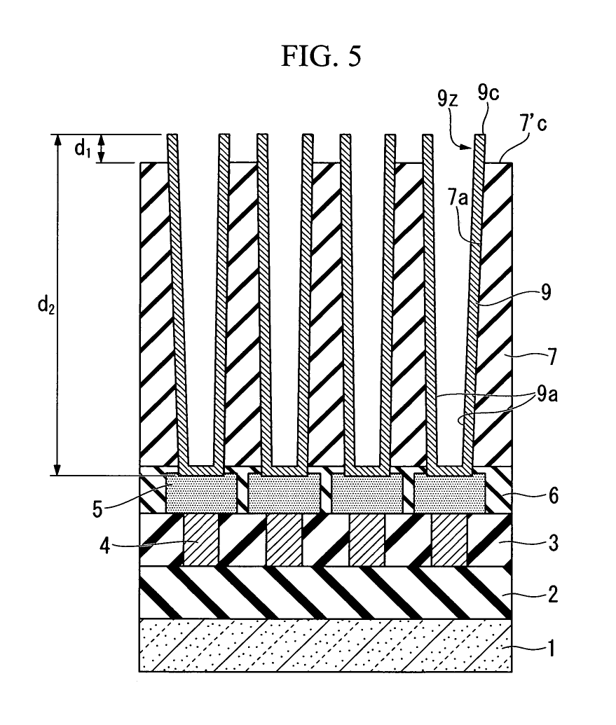

The lower electrode 9 is not etched by the wet etching. Consequently, an upper portion of the lower electrode 9 protrudes from a new upper surface 7′c of the fourth insulating film 7 after the wet etching process, as shown in FIG. 5, which is hereinafter called a protruding portion 9z. A length d₁ of the protruding portion 9z, which is from the level of the new surface 7′c of the fourth insulating film 7 to the level of a top surface 9c of the lower electrode 9, is, for example, approximately 50 nm.

Preferably, the length d₁ of the protruding portion 9z is 1% to 15% of a depth d₂ of the hole 7a. If the length d₁ of the protruding portion 9z is 1% of the depth d₂ of the hole 7a or less, a support film, which will be formed in a later process, becomes too thin to stably support the lower electrode 9. If the length d₁ of the protruding portion 9z is 15% of the depth d₂ of the hole 7a or more, the support film becomes too thick, thereby causing a load on the lower electrode 9 and therefore causing the lower electrode 9 to fall.

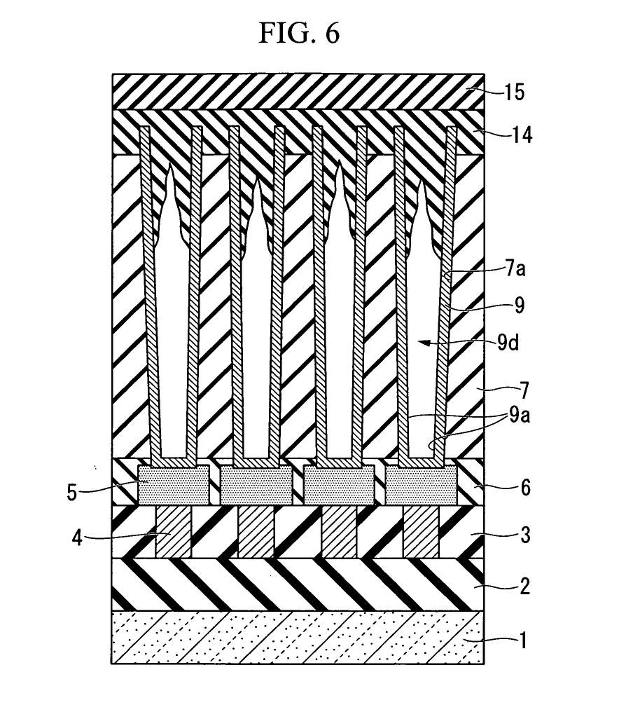

Then, a carbon film 14 is formed over the fourth insulating film 7 by using plasma CVD, as shown in FIG. 6. Preferably, a thickness of the carbon film 14 is greater than the length d₁ of the protruding portion 9z so that the top surface 9c of the protruding portion 9z is covered by the carbon film 14. In this case, the carbon film 14 does not completely fill the hole 7a. The carbon film 14 covers the upper and side surfaces of the protruding portion 9z and an upper portion of an inner surface 9a of the lower electrode 9. At the same time, a space 9d remains in the hole 7a.

The carbon film 14 includes, for example, an amorphous carbon (α-C) film. The carbon film 14 is formed by using, for example, parallel plate plasma CVD, at a source power of 1000 W, at a pressure of 5 Toor, at a processing temperature of 500° C., with a process gas containing C₂F₄ (ethylene) and Ar (argon) at a flow rate of C₂F₄/Ar=2000/5000 sccm, for a processing time of 60 seconds (when the carbon film 14 is formed in a thickness of 100 nm). The thickness of the carbon film 14 is approximately 100 nm, but is not limited thereto. The thickness of the carbon film 14 is adjusted according to the length d₁ of the protruding portion 9z.

Then, an insulating film 15, made of a silicon oxide film, is formed over the carbon film 14 by using plasma CVD. The insulating film 15 is an etching protection film. The insulating film 15 is formed by using, for example, parallel plate plasma CVD, at a source power of 100 W, at a pressure of 5 Toor, at a processing temperature of 400° C., with a process gas containing SiH₄ (mono-silane), N₂O (nitrous oxide), and He (helium) at a flow rate of SiH₄/N₂O/He=100/1000/9000 sccm, for a processing time of 10 seconds (when the insulating film 15 is formed in a thickness of 20 nm). The thickness of the insulating film 15 is approximately 20 nm, but is not limited thereto. The thickness of the insulating film 15 is adjusted according to the thickness of the carbon film 14.

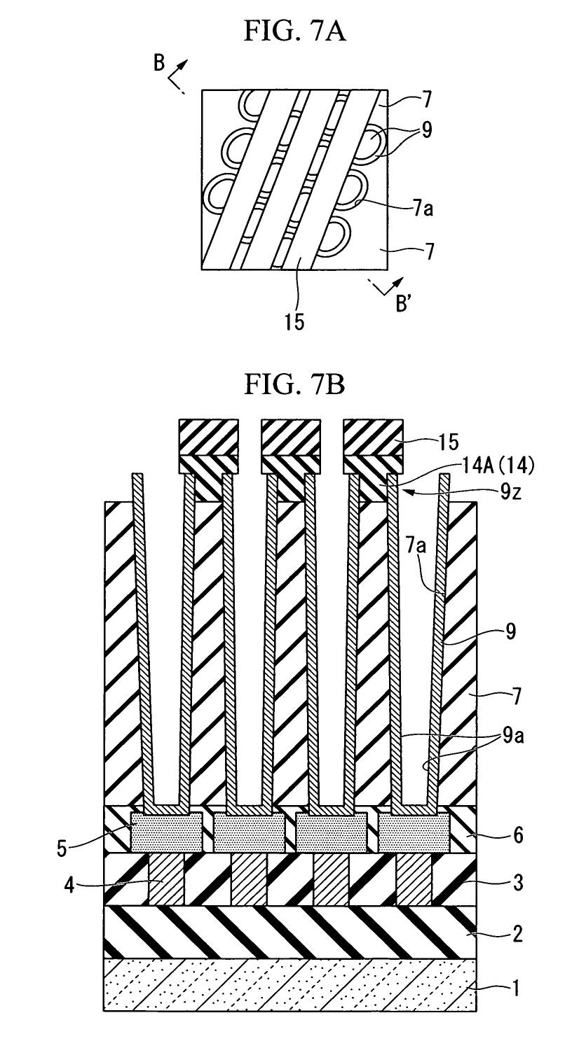

Then, a resist film is formed over the insulating film 15. Then, a resist mask is formed by using photolithography. Then, the insulating film 15 is dry etched using the resist mask until an upper surface of the carbon film 14 is exposed, as shown in FIGS. 7A and 7B. The dry etching is carried out by using parallel plate RIE, at a source power of 500 W, at a pressure of 50 mTorr, at a wafer temperature of 20° C., with a process gas containing CF₄ (carbon tetrafluoride) at a flow rate of 100 sccm, for a processing time of 30 seconds (when the thickness of the insulating film 15 is 20 nm). The processing time for the dry etching is adjusted according to the thickness of the insulating film 15.

Then, the carbon film 14 is dry etched using the insulating film 15 as a hard mask until the inner surface 9a of the lower electrode 9 is completely exposed. Thus, a carbon support film 14A is formed. The dry etching is carried out by using parallel plate RIE, at a source power of 500 W, at a pressure of 20 mTorr, at a wafer temperature of 20° C., with a process gas containing O₂ (oxygen) and Ar (argon) at a flow rate of O₂/Ar=100/100 sccm, for a processing time of 60 seconds (when the thickness of the carbon film 14 is 100 nm). The processing time for the dry etching is adjusted according to the thickness of the carbon film 14. When the carbon film 14 is dry etched, the resist mask over the insulating film 15 is removed at the same time.

When multiple insulating films 15 are viewed in plan view as shown in FIG. 7A, the insulating films 15 have the same width and are equally spaced. Each of the insulating films 15 partially overlaps the lower electrodes 9 arranged in a matrix.

When the insulating films 15 are viewed in a cross-sectional view as shown in FIG. 7B, a carbon support film 14A is formed so as to connect the protruding portions 9z of the lower electrodes 9 that are arranged in a line under each carbon support film 14A. The carbon support film 14A covers an outer side surface of the protruding portion 9z, and covers the top surface 9c of the protruding portion 9z. Each insulating film 15 covers an upper surface of the carbon support film 14A.

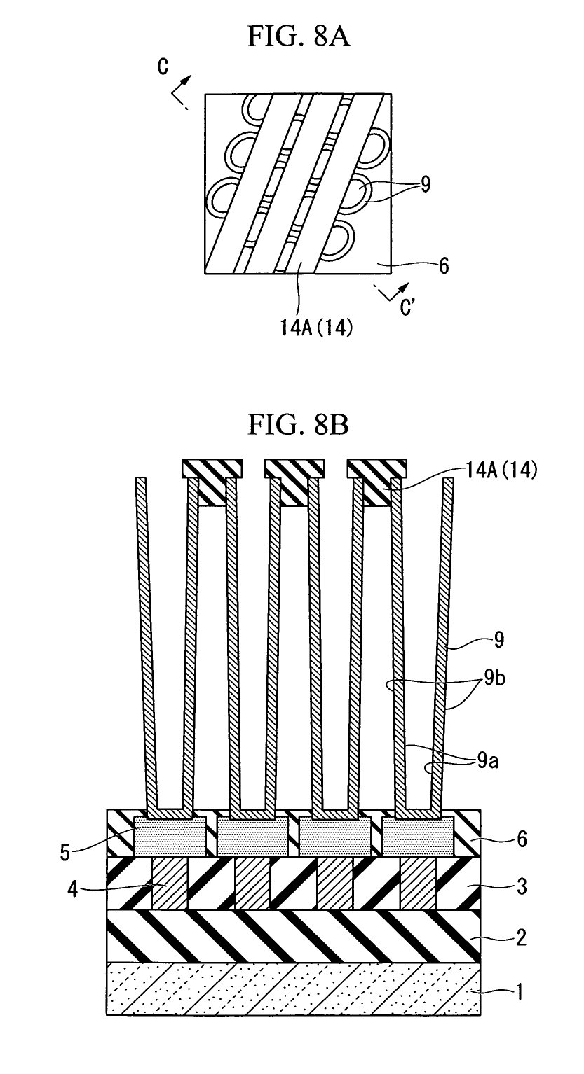

Then, the fourth insulating film 7 and the insulating film 15 are removed by a wet etching process, as shown in FIGS. 8A and 8B. The wet etching process is carried out using an etching solution containing 49% hydrofluoric acid by weight, at a solution temperature of 20° C., at an etching rate of a silicon oxide film of 67 nm/min (when plasma CVD is used), for a processing time of 34 seconds.

An outer side surface 9b of the lower electrode 9 is exposed by the wet etching process. In this case, the carbon support film 14A is not wet-etched, remains so as to connect the top surfaces 9c of the lower electrodes 9, and thereby mechanically supports the lower electrodes 9. Therefore, even if adjacent lower electrodes 9 gravitate toward each other due to surface tension of the wet etching solution, the lower electrodes 9 do not fall.

Since the third insulating film 6 functions as a stopper film and covers the pad 5 and the second insulating film 3, the second insulating film 3 under the pad 5 and the third insulating film 6 is not removed and remains.

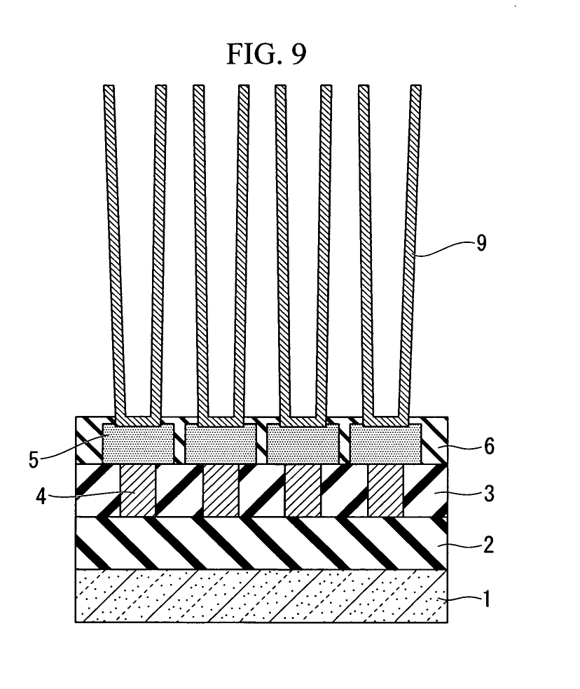

Then, the carbon support film 14A is removed by an ashing process, as shown in FIG. 9. The ashing process is carried out by using an ICP (Inductively Coupled Plasma) method, at a source power of 4000 W, at a stage temperature of 250° C., with a process gas containing oxygen (O₂) at a rate of 10000 sccm, for a processing time of 60 seconds (when a thickness of an amorphous carbon film is 100 nm). The ashing process time is adjusted according to the thickness of the carbon support film 14A.

As shown in FIG. 9, multiple lower electrodes 9 having the same diameter and height are arranged at a predetermined pitch over the third insulating film 6. Thus, the carbon support film 14A is removed by using the ashing process that is a thy etching process, instead of using a wet etching process that causes surface tension to act on the lower electrodes 9. Therefore, the lower electrodes 9 do not fall.

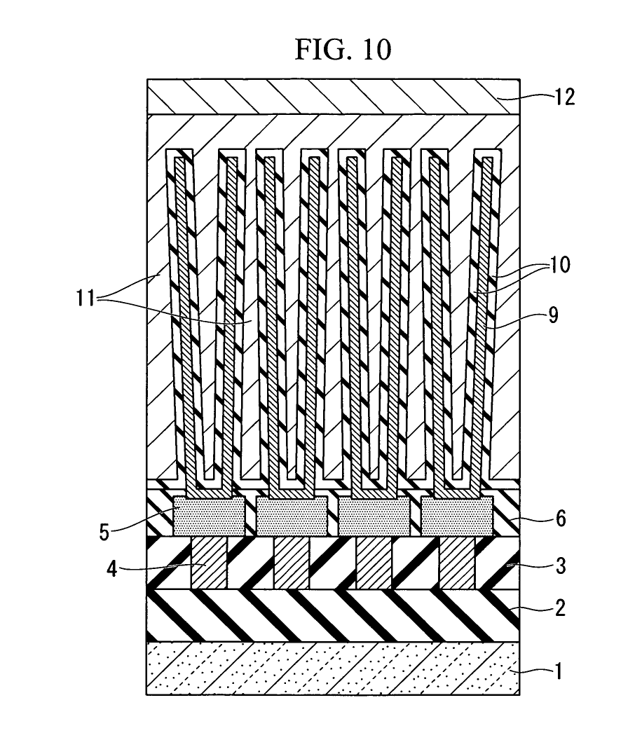

Then, a capacitor insulating film 10, which has a multi-layered structure including an aluminum oxide film and a zirconium oxide film, is formed in a thickness of approximately 7 nm by using ALD (Atomic Layer Deposition) so as to cover exposed surfaces of the lower electrodes 9 and an exposed upper surface of the third insulating film 6, as shown in FIG. 10.

Then, an upper electrode 11, which has a multi-layered structure including a titanium nitride film and a boron-doped silicon germanium film, is formed by using CVD. The thicknesses of the titanium nitride film and the boron-doped silicon germanium film are approximately 10 nm and 150 nm, respectively. Then, a tungsten film having a thickness of 100 nm is formed over the upper electrode 11 by using spattering. The tungsten film forms a plate electrode 12. As shown in FIG. 10, the lower electrode 9 and the capacitor insulating film 10 are included in the upper electrode 11.

Then, the plate electrode 12, the upper electrode 11, and the capacitor insulating film 10 are patterned by using photolithography and dry etching to form a capacitor, as shown in FIG. 10. Then, an insulating film is formed over the plate electrode 12, and then is planarized by using CMP. Then, upper wires are formed. Thus, a desired semiconductor device can be obtained.

According to the first embodiment, the carbon support film 14A having excellent wet etching resistance is used in the wet etching process. For this reason, even after the wet etching process, the carbon support film 14A remains with a sufficient thickness and can stably support the lower electrodes 9, thereby preventing the lower electrodes 9 from falling. Additionally, the carbon support film 14A can be precisely formed at a desired position after the hole 7a and the lower electrode 9 are formed, thereby preventing a variation in size of the hole 7a and a deformation of the hole 7a. For this reason, a semiconductor device including the lower electrodes 9 in a uniform size and shape can be manufactured.

Additionally, the capacitor insulating film 10 is formed after the carbon support film 14A is removed. Then, the upper electrode 11 is formed so as to cover the capacitor insulating film 10, thereby preventing a variation in size and a deformation of the hole 7a. For this reason, a semiconductor device including the lower electrodes 9 in a uniform size and shape can be manufactured.

Further, the carbon support film 14A is removed by using plasma ashing, instead of using wet etching that causes surface tension to act on adjacent lower electrodes 9, thereby preventing the lower electrodes 9 from falling.

Moreover, the length d₁, which is from the level of the upper surface 7′c of the fourth insulating film 7 to the level of the top surface 9c of the lower electrode 9, is in the range of 1% to 15% of the depth d₂ of the hole 7a, thereby preventing a variation in size and a deformation of the hole 7a. For this reason, a semiconductor device including the lower electrodes 9 in uniform size and shape can be manufactured.

Additionally, the carbon film 14, made of an amorphous carbon film having excellent wet etching resistance, is used. For this reason, even after the wet etching process, the carbon support film 14A remains with a sufficient thickness and can stably support the lower electrodes 9, thereby preventing the lower electrodes 9 from falling.

### Second Embodiment

Hereinafter, a method of manufacturing a semiconductor device according to a second embodiment of the present invention is explained. The like reference numerals denote the like elements between the first and second embodiments.

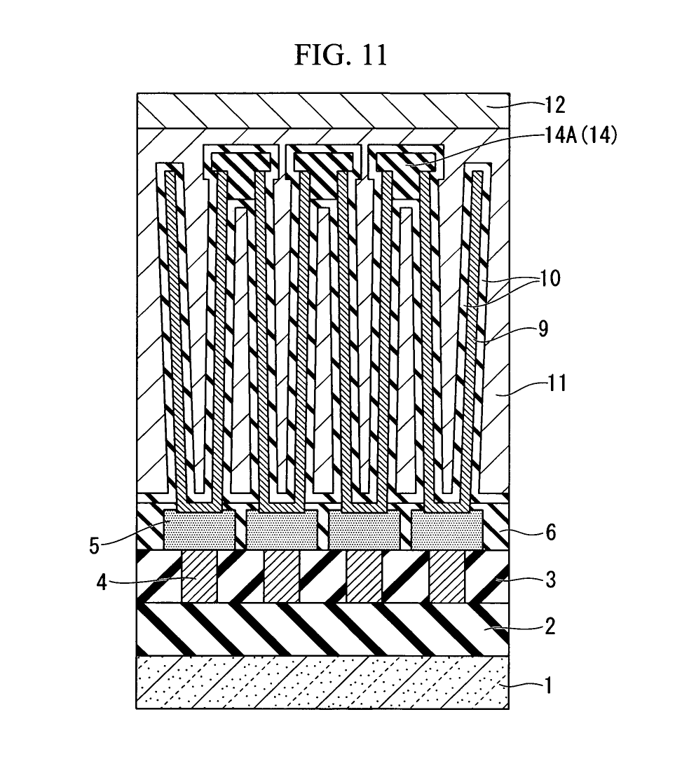

Firstly, a structure shown in FIGS. 8A and 8B is formed by similar processes as shown in FIGS. 1 to 8B of the first embodiment. Then, a capacitor insulating film 10, which has a multi-layered structure including an aluminum oxide film and a zirconium oxide film, is formed in a thickness of approximately 7 nm by using ALD (Atomic Layer Deposition) so as to cover exposed surfaces of the lower electrodes 9, the third insulating film 6, and the carbon support film 14A, as shown in FIG. 11.

Then, an upper electrode 11, which has a multi-layered structure including a titanium nitride film and a boron-doped silicon germanium film, is formed by using CVD. Thicknesses of the titanium nitride film and the boron-doped silicon germanium film are approximately 10 nm and 150 nm, respectively. Then, a tungsten film having a thickness of 100 nm is formed over the upper electrode 11 using spattering. The tungsten film forms a plate electrode 12. As shown in FIG. 11, the lower electrode 9 and the capacitor insulating film 10 are included in the upper electrode 11.

Then, the plate electrode 12, the upper electrode 11, and the capacitor insulating film 10 are patterned by using photolithography and dry etching to form a capacitor. Then, an insulating film is formed over the plate electrode 12, and then is planarized by using CMP. Then, upper wires are formed. Thus, a desired semiconductor device can be obtained.

Although it has been explained in the first embodiment that the carbon support film 14A is removed, the carbon support film 12A is an insulating film, and therefore can remain as explained in the second embodiment.

According to the second embodiment, the same effects as those of the first embodiment can be achieved.

### First Example

Hereinafter, a first example of the present invention is explained in detail. However, the present invention is not limited thereto.

An isolation region and a diffusion region were formed on an upper surface of a silicon substrate that had been subjected to a cleaning process. Then, a silicon oxide film (first insulating film) was formed over the silicon substrate. A transistor and a wire were formed in the first insulating film.

Then, another silicon oxide film (second insulating film) was formed over the first insulating film. Then, a contact hole was formed in the second insulating film. Then, a conductive material was provided to fill the contact hole, and thus a contact was formed.

Then, a pad, made of poly-silicon (p-Si), was formed on an upper surface of the second insulating film so as to be connected to the contact. The contact electrically connected the transistor and the wire, which were formed in the first insulating film, to the pad.

Then, a third insulating film (stopper film), made of a silicon nitride film having a thickness of 50 nm, was formed by using low-pressure CVD so as to cover the second insulating film and the pad.

Then, a BPSG film was formed over the stopper film by using normal-pressure CVD. Then, a silicon oxide film was formed over the BPSG film by using plasma CVD. Thus, a multi-layered film (fourth insulating film) including the BPSG film and the silicon oxide film was formed in a thickness of, for example, 2.2 μm. Then, the thickness of the fourth insulating film is reduced from the upper surface thereof by 200 nm by using CMP. Thus, the upper surface of the fourth insulating film was planarized.

Then, a resist film is formed over the fourth insulting film. Then, a resist mask was formed over the fourth insulating film by using photolithography so as to partially cover the upper surface of the fourth insulating film. Consequently, the upper surface of the fourth insulating film is partially exposed.

Then, the fourth insulating film was dry etched using the resist mask until a part of the pad was exposed. A diameter of the hole at a level of the upper surface of the resist mask was 85 nm. A depth of the hole was 2.0 μm. The dry etching process was carried out by using parallel plate RIE, at a source power of 1500 W, at a pressure of 20 mTorr, at a wafer temperature of 20° C., with a process gas containing C₄F₆ (hexafluoro-1, 3-butadiene), CHF₃ (trifluoromethane), O₂ (oxygen), Ar (argon) at a flow rate of C₄F₆/CHF₃/O₂/Ar=30/30/25/400 sccm.

Then, the resist mask was removed. Then, a multi-layered structure including a titanium nitride film and a titanium film was formed in a thickness of, for example, 25 nm so as to cover an inner surface of the hole and the upper surface of the fourth insulating film. Then, only a portion of the multi-layered structure, which covered the upper surface of the fourth insulating film, was removed using photolithography and dry etching. Thus, a remaining portion of the multi-layered structure, which covered the inner surface of the hole, formed a lower electrode.

Then, a thickness of the fourth insulating film was uniformly reduced from the upper surface thereof by 50 nm by a wet etching process. The wet etching process was carried out, by using a buffer hydrofluoric acid solution containing HF (hydrofluoric acid) and NH₄F (ammonium fluoride) at a composition ratio of HF:NH₄F=0.1 wt %:20 wt %, at a solution temperature of 20° C., at an etching rate of silicon oxide of 10 nm/min (when plasma CVD is used), for a processing time of 5 seconds.

Consequently, an upper portion of the lower electrode 9 protruded from the etched upper surface of the fourth insulating film after the wet etching process. A length d₁ of the protruding portion was approximately 50 nm, which was 2.5% of a depth d₂ (2.0 μm) of the hole.

Then, an amorphous carbon film having a thickness of 100 nm was formed by using plasma CVD so as to cover the fourth insulating film and the lower electrode. The amorphous carbon film was formed by using a parallel plate plasma method, at a source power of 1000 W, at a pressure of 5 Toor, at a processing temperature of 500° C., with a process gas containing C₂F₄ (ethylene) and Ar (argon) at a flow rate of C₂F₄/Ar=2000/5000 sccm, for a processing time of 60 seconds (when the carbon film having the thickness of 100 nm was formed). Consequently, the amorphous carbon film did not completely fill the hole, but filled only an upper portion of the hole.

Then, another silicon oxide film (fifth insulating film) having a thickness of 20 nm was formed using plasma CVD. The fifth insulating film was formed by using parallel plate plasma method, at a source power of 100 W, at a pressure of 5 Toor, at a processing temperature of 400° C., with a process gas containing SiH₄ (mono-silane), N₂O (nitrous oxide), and He (helium) with a flow rate of SiH₄/N₂O/He=1000/1000/9000 sccm, for a processing time of 10 seconds (when the fifth insulating film having the thickness of 20 nm was formed).

Then, a resist film was formed over the fifth insulating film. Then, a resist mask was formed by using photolithography. Then, the fifth insulating film was dry etched using the resist mask until an upper surface of the amorphous carbon film was exposed. The dry etching process was carried out by using parallel plate RIE, at a source power of 500 W, at a pressure of 50 mTorr, at a wafer temperature of 20° C., with a process gas containing CF₄ (carbon tetrafluoride) with a flow rate of 100 sccm, for a processing time of 30 seconds (when the thickness of the insulating film was 20 nm).

Then, the amorphous carbon film was dry etched using the etched fifth insulating film as a hard mask until the lower electrode was exposed. At the same time, the fifth insulating film over the amorphous carbon film was removed by dry etching the amorphous carbon film. The dry etching was carried out by using parallel plate RIE, at a source power of 500 W, at a pressure of 20 mTorr, at a wafer temperature of 20° C., with a process gas containing O₂ (oxygen) and Ar (argon) at a flow rate of O₂/Ar=100/100 sccm, for a processing time of 60 seconds (when the thickness of the carbon film was 100 nm).

Then, the fourth insulating film was removed by a wet etching process so that an outer surface of the lower electrode was exposed. The wet etching process was carried out using an etching solution containing 49% hydrofluoric acid by weight, at a temperature of 20° C., at an etching rate of a silicon oxide film of 67 nm/min (when plasma CVD is used), for a processing time of 34 seconds.

Then, the amorphous carbon film between each lower electrode was removed by an ashing process. The ashing process was carried out by using an ICP (Inductively Coupled Plasma) method, at a source power of 4000 W, at a stage temperature of 250° C., with a process gas containing oxygen (O₂) at a flow rate of 10000 sccm, for a processing time of 60 seconds (when a thickness of an amorphous carbon film was 100 nm).

Then, a capacitor insulating film, having a multi-layered structure including an aluminum oxide film and a zirconium oxide film, was formed in a thickness of 7 nm by using ALD (Atomic Layer Deposition).

Then, an upper electrode, having a multi-layered structure including a titanium nitride film and a boron-doped silicon germanium film, was formed by using CVD. Thicknesses of the titanium nitride film and the boron-doped silicon germanium film were 10 nm and 150 nm, respectively. Then, a plate electrode, made of a tungsten film having a thickness of 100 nm, was formed over the upper electrode by using spattering.

Then, the plate electrode, the upper electrode, and the capacitor insulating film were patterned by using photolithography and dry etching to form a capacitor. Then, an insulating film was formed over the plate electrode, and then was planarized by using CMP. Then, upper wires were formed. Thus, a semiconductor device of the first example was formed.

According to the manufacturing processes of the first example, the lower electrode did not fall when the fourth insulating film was wet-etched and when the amorphous carbon film was removed by the asking process. It was guessed that the carbon support film having excellent wet-etching resistance was used so that the carbon support film remained with a sufficient thickness after the wet etching process, and thereby the lower electrode was prevented from falling.

Further, the carbon support film was formed after the hole and the lower electrode were formed. For this reason, a variation in size and a deformation of the hole and the lower electrode did not occur, and thereby a semiconductor device including a capacitor having stable characteristics could be formed.

### Second and Third Examples, and First and Second Comparative Examples

In a first comparative example, the depth d₁ of the protruding portion was set to be 0.5% (10 nm) of the depth d₂ (2.0 μm) of the hole. In a second example, the depth d₁ of the protruding portion was set to be 1.0% (20 nm) of the depth d₂ (2.0 μm) of the hole. In a third example, the depth d₁ of the protruding portion was set to be 15% (300 nm) of the depth d₂ (2.0 μm) of the hole. In a second comparative example, the depth d₁ of the protruding portion was set to be 17% (340 nm) of the depth d₂ (2.0 μm) of the hole.

In the first comparative example, there were some portions where the support film was not formed, and the lower electrode fell. In the second comparative example, some support films collapsed, and the lower electrode fell. In the second and third examples, the lower electrode did not fall when the fourth insulating film was wet-etched and when the amorphous carbon film was removed by the ashing process. It was guessed that the carbon support film having excellent wet-etching resistance was used so that the carbon support film remained with a sufficient thickness after the wet etching process, and thereby the lower electrode was prevented from falling.

Further, the carbon support film was formed after the hole and the lower electrode were formed. For this reason, a variation in size and a deformation of the hole and the lower electrode did not occur, and thereby a semiconductor device including a capacitor having stable characteristics could be formed.

### Fourth Example

A semiconductor device of a fourth example was formed in a similar manner as the first example except that the support film was not removed. In the fourth example, the lower electrode did not fall when the fourth insulating film was wet etched and when the amorphous carbon film was removed by the ashing process. It was guessed that the carbon support film having excellent wet-etching resistance was used so that the carbon support film remained with a sufficient thickness after the wet etching process, and thereby the lower electrode was prevented from falling.

Further, the carbon support film was formed after the hole and the lower electrode were formed. For this reason, a variation in size and a deformation of the hole and the lower electrode did not occur, and thereby a semiconductor device including a capacitor having stable characteristics could be formed.

### Third Comparative Example

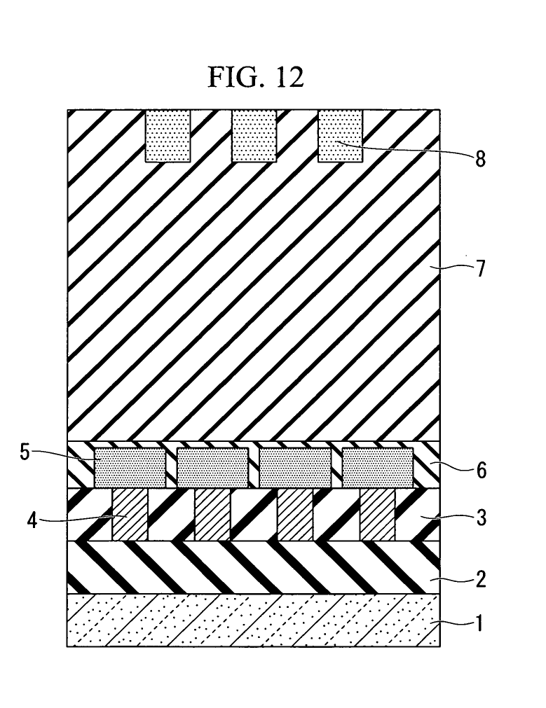

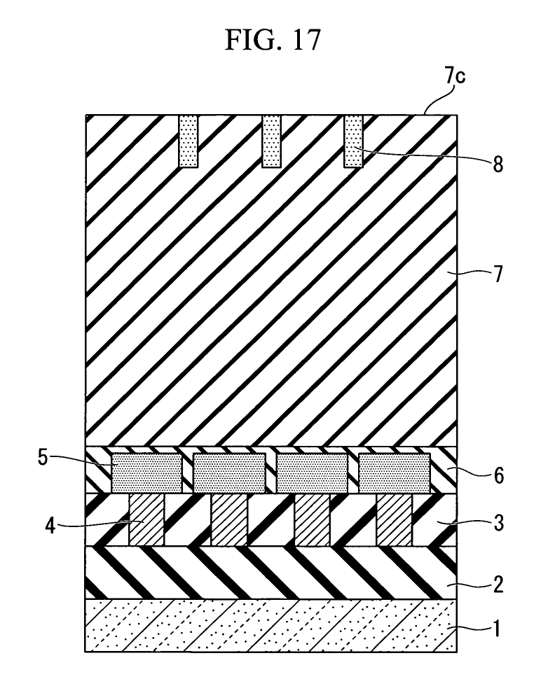

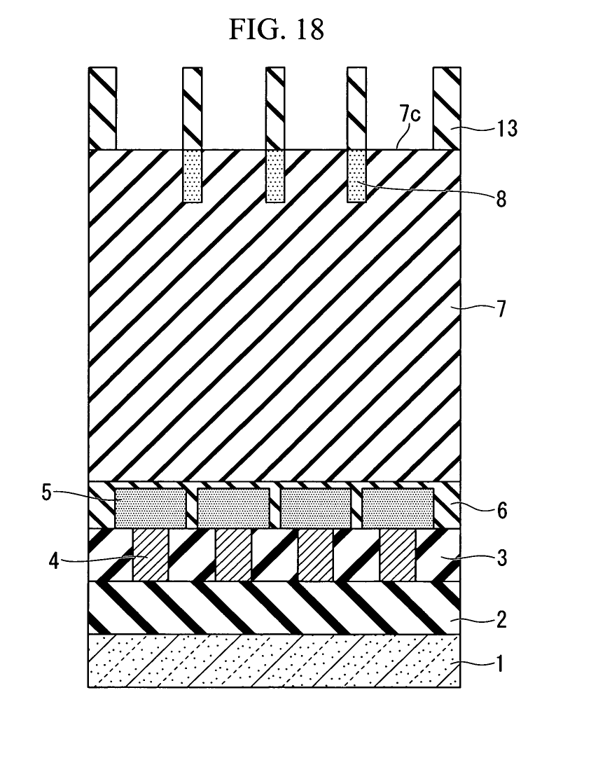

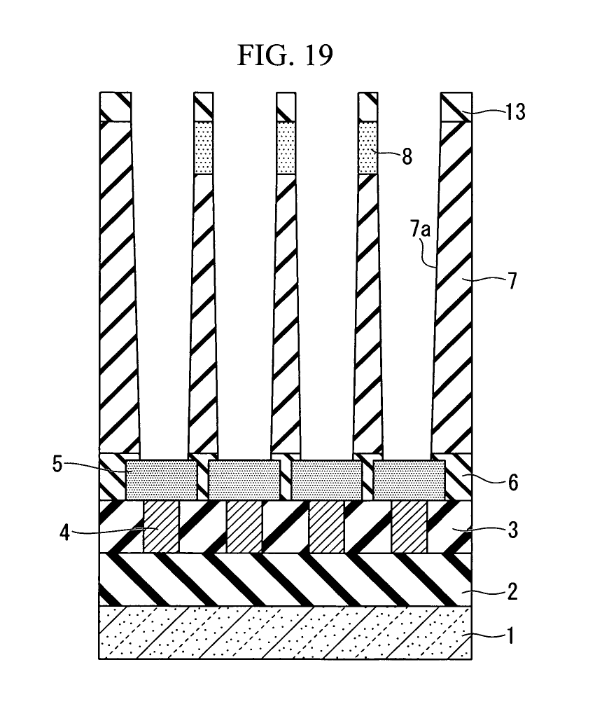

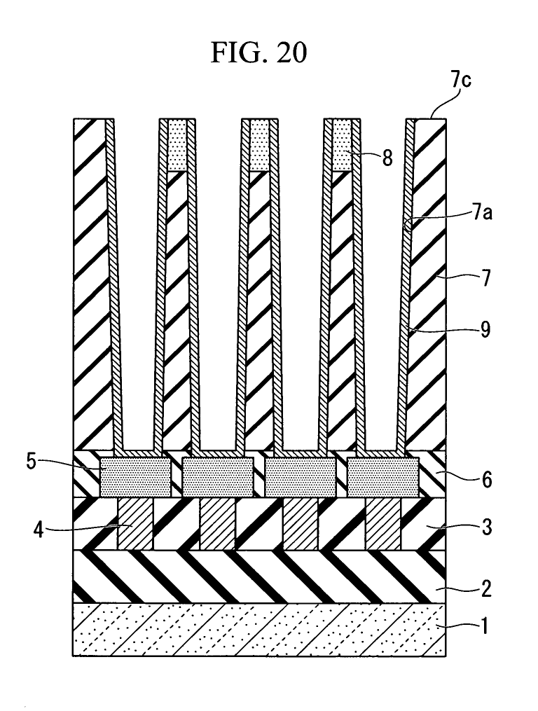

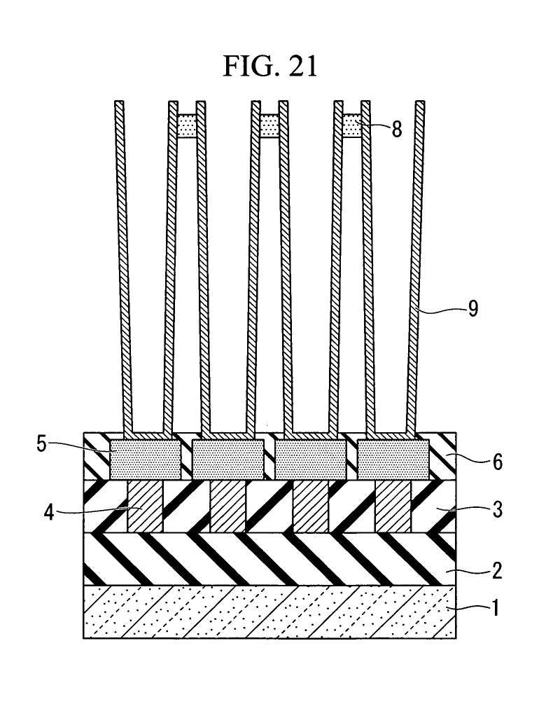

FIGS. 12 to 18 are cross-sectional views indicative of a process flow illustrating a method of manufacturing a semiconductor device according to a third comparative example of the present invention. Like reference numerals denote like elements between the first embodiment and the third comparative example.

Firstly, the first inter-layer insulating film 2 was formed over the upper surface 1a of the substrate 1. A transistor and a wire were formed in the first inter-layer insulating film 2. Then, the second inter-layer insulating film 3 was formed over the first inter-layer insulating film 2. Then, a through hole was formed in the second inter-layer insulating film 3. Then, the contact 4 was formed so as to fill the through hole.

Then, the pad 5, made of poly-silicon, was formed on an upper surface of the second inter-layer insulating film 3 so as to be connected to the contact 4. The contact 4 electrically connected the transistor and the wire, which were formed in the first inter-layer insulating film 2, to the pad 5.

Then, the third inter-layer insulating film (stopper film) 6, made of a silicon nitride film having a thickness of 50 nm, was formed by using low-pressure CVD so as to cover the second inter-layer insulating film 3 and the pad 5.

Then, a BPSG film was formed over the stopper film 6 by using normal-pressure CVD. Then, a silicon oxide film was formed over the BPSG film by using plasma CVD. Thus, a multi-layered film (fourth inter-layer insulating film 7) including the BPSG film and the silicon oxide film was formed in a thickness of, for example, 2.2 μm.

Then, the thickness of the fourth inter-layer insulating film 7 was reduced from the upper surface thereof by 200 nm by using CMP. Thus, the upper surface of the fourth inter-layer insulating film 7 was planarized.

Then, a groove pattern, having a depth of 125 nm, was formed in the fourth inter-layer insulting film 7, adjacent to the upper surface of the fourth inter-layer insulting film 7 by using photolithography and dry etching. Then, a silicon nitride film was formed so as to fill the groove pattern by using low-pressure CVD. A portion of the silicon nitride film, which was over the fourth inter-layer insulating film 7, was removed by using CMP. Thus, the support film 8 filling the groove pattern was formed, as shown in FIG. 12.

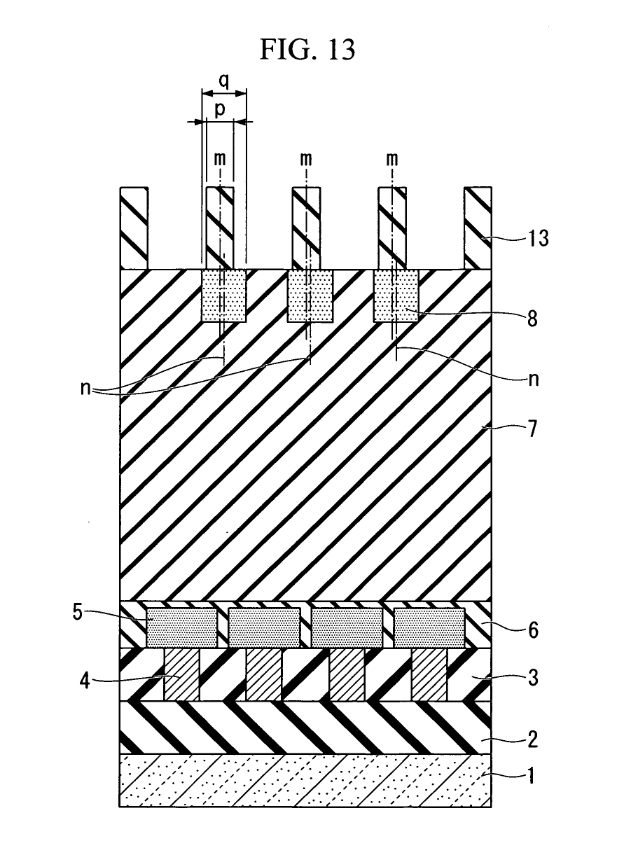

Then, a resist film was formed over the fourth inter-layer insulating film 7. Then, the resist film was patterned by using photolithography to form the resist mask 13, as shown in FIG. 13.

Due to the lack of precision of the photolithography for forming the groove pattern, a width q of the support film 8 was wider than a width p of the resist mask 13. Further, due to the lack of precision of the photolithography for forming the resist mask 13, center line m of the resist mask 13 did not match center line n of the support film 8.

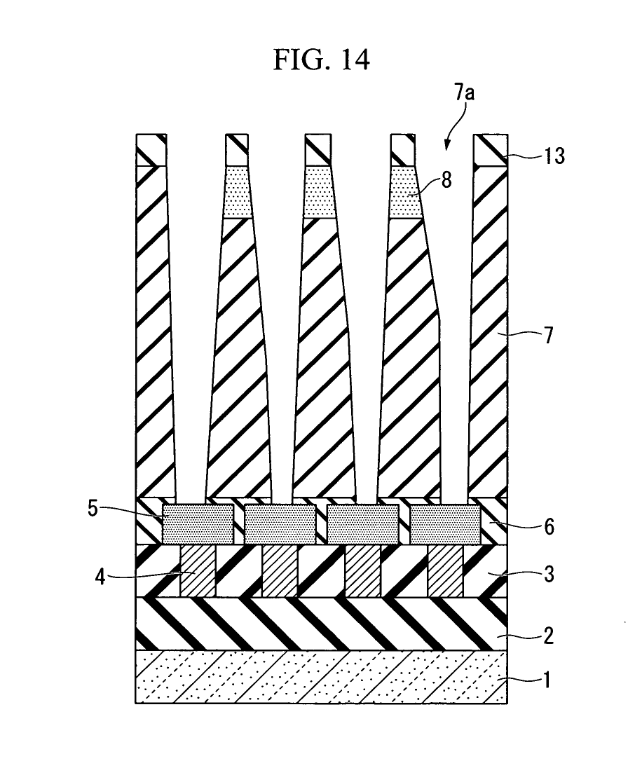

Then, the fourth inter-layer insulating film 7 and the third inter-layer insulating film (stopper film) 6 were dry etched using the resist mask 13 until a part of the pad 5 was exposed. Thus, the hole 7a was formed. Since the support film 8 was larger in width than the resist mask 13 as shown in FIG. 13, the support film 8 partially overlapped the hole 7a in plan view. For this reason, a portion of the support film 8 and a portion of the third inter-layer insulating film 7, which overlap the hole 7a in plan view, are simultaneously etched. In this case, an oxide film is easily etched compared to a nitride film. The etching rate of the support film 8 is smaller than that of the third inter-layer insulating film 7. The third inter-layer insulating film 7 is the silicon oxide film, and the support film 8 is the silicon nitride film. For this reason, an etching surface of the third inter-layer insulating film 7 became perpendicular to the horizontal surface of the third inter-layer insulating film 6. However, an etching surface of the support film 8 became inclined inwardly, as shown in FIG. 14. Each hole 7a was not formed in uniform shape.

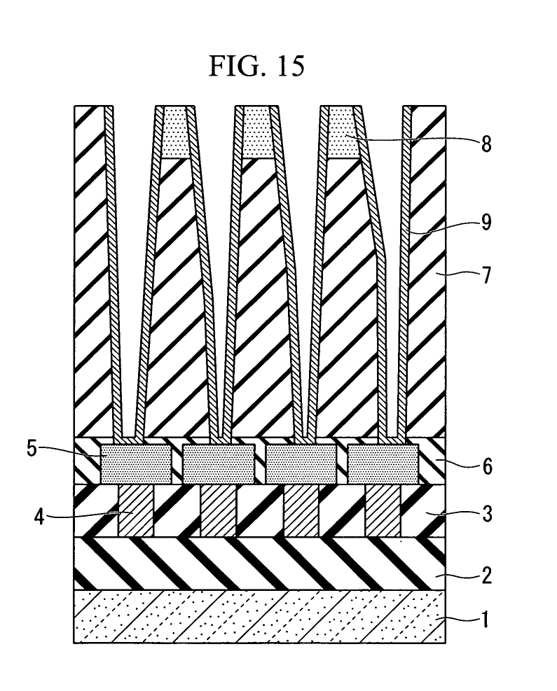

Then, the resist mask 13 was removed. Then, a multi-layered structure including a titanium nitride film and a titanium film was formed in a thickness of 25 nm so as to cover an inner surface of the hole 7a (i.e., an upper surface of the pad 5 and side surfaces of the third inter-layer insulating film 7 and the support film 8). Then, only a portion of the multi-layered structure, which covers the upper surface of the support film 8, was removed by using photolithography and dry etching. Thus, a remaining portion of the multi-layered structure, which covers the inner surface of the hole 7a, formed the lower electrode 9, as shown in FIG. 15.

Then, the fourth inter-layer insulating film 7 was removed by using wet-etching process. The wet etching process was carried out by using a wet etching solution containing 49% fluoric acid by weight, at a solution temperature of 20° C., at an etching rate of the silicon oxide film of 67 nm/sec (when plasma CVD is used), for a processing time of 34 seconds.

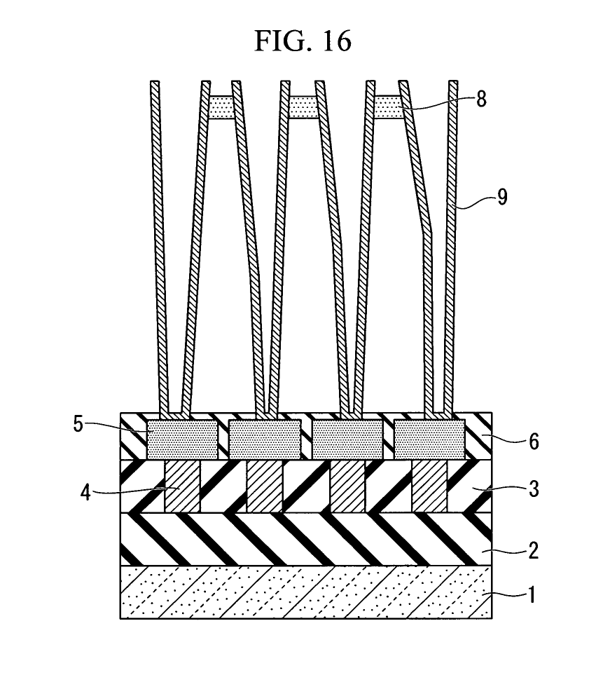

Then, an outer side surface of the cylindrical lower electrode 9 was exposed by a wet etching process, as shown in FIG. 16. A thickness of the support film 8, which connected the top surfaces of the lower electrodes 9, was reduced by the wet etching process by 37.5 nm from each of the upper and lower surfaces of the support film 8.

The thickness of the remaining support film 8 was 50 (=125−75) nm. Although the lower electrode 9 did not fall while the fourth inter-layer insulating film 7 was wet etched, a variation in size of the lower electrode 9 and a deformation of the lower electrode 9 occurred.

The present invention is applicable to industries that manufacture and utilize semiconductor devices.

As used herein, the following directional terms “forward,” “rearward,” “above,” “downward,” “vertical,” “horizontal,” “below,” and “transverse,” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percent of the modified term if this deviation would not negate the meaning of the word it modifies.

It is apparent that the present invention is not limited to the above embodiments, but may be modified and changed without departing from the scope and spirit of the invention.

For example, in one embodiment, a semiconductor device may include, but is not limited to: a pad over a semiconductor substrate; a first insulating film covering the pad and the semiconductor substrate; a first electrode upwardly extending from the first insulating film, the first electrode being electrically connected to the pad; a second insulating film covering the first insulating film and the first electrode; and a second electrode covering the second insulating film.

Regarding the above semiconductor device, the first electrode is cylindrical.

Regarding the above semiconductor device, the first electrode is cylindrical, and a diameter of the first electrode becomes smaller as a level of the first electrode decreases.

Regarding the above semiconductor device, the second insulating film covers an upper surface of the first insulating film, and top, inner, and outer surfaces of the first electrode.

Regarding the above semiconductor device, the support film includes an amorphous carbon film.

In another embodiment, a semiconductor device may include, but is not limited to: first and second pads over a semiconductor substrate; a first insulating film covering the first and second pads and the semiconductor substrate; first and second electrodes upwardly extending from the first insulating film, the first and second electrodes being electrically connected to the first and second pads, respectively; a support film connecting first and second upper portions of the first and second electrodes; a second insulating film covering the first insulating film, the first and second electrodes, and the support film; and a third electrode covering the second insulating film.

Regarding the above semiconductor device, the first and second electrodes are cylindrical.

Regarding the above semiconductor device, the first and second electrodes are cylindrical, and first and second diameters of the first and second electrodes become smaller as first and second levels of the first and second electrodes decrease.

Regarding the above semiconductor device, the second insulating film covers an upper surface of the first insulating film, top, inner, and outer surfaces of the first and second electrodes, and the support film.

Regarding the above semiconductor device, first and second vertical dimensions of the first and second upper portions are in the range of 1 percent to 15 percent of the first and second depths of the first and second electrodes, respectively.

Regarding the above semiconductor device, the support film includes an amorphous carbon film.

What is claimed is:

1. A method of manufacturing a semiconductor device, comprising:
forming first and second electrodes in a first insulating film over a semiconductor substrate, the first and second electrodes upwardly extending from the semiconductor substrate, the first and second electrodes having first and second upper portions protruding from an upper surface of the first insulating film, respectively;
forming a support film which covers the upper surface of the first insulating film and the first and second upper portions;
patterning the support film so that a remaining portion of the support film connects the first and second upper portions; and
removing the first insulating film while the remaining portion mechanically supports the first and second electrodes.

2. The method according to claim 1, wherein forming the first and second electrodes comprises:
forming first and second holes in a second insulating film over the semiconductor substrate;
forming the first and second electrodes which cover first and second inner surfaces of the first and second holes, respectively; and
selectively etching the second insulating film so that the first and second upper portions protrude from an etched upper surface of the second insulating film, and the second insulating film selectively etched forming the first insulating film.

3. The method according to claim 1, further comprising:
after removing the first insulating film, forming, while the remaining portion mechanically supports the first and second electrodes, a capacitor insulating film which covers the remaining portion of the support film and the first and second electrodes; and
forming a third electrode which covers the capacitor insulating film.

4. The method according to claim 1, further comprising:
after removing the first insulating film, removing the remaining portion;
forming a capacitor insulating film which covers the first and second electrodes; and
forming a third electrode which covers the capacitor insulating film.

5. The method according to claim 4, wherein the remaining portion is removed by a plasma ashing process.

6. The method according to claim 2, wherein selectively removing the second insulating film is stopped when first and second vertical dimensions of the first and second upper portions become in the range of 1 percent to 15 percent of the first and second depths of the first and second holes, respectively.

7. The method according to claim 1, wherein the support film is made of an amorphous carbon film.

8. The method according to claim 2, further comprising:
forming the semiconductor substrate;
forming first and second pads over the semiconductor substrate;
forming an etching stopper film which covers the first and second pads and the semiconductor substrate; and
forming the second insulating film which covers the etching stopper film,
wherein the first and second electrodes are formed so as to be in contact with the first and second pads, respectively.

9. The method according to claim 1, wherein the first insulating film is removed by a wet etching process.

10. The method according to claim 2, wherein the first and second holes are formed by a dry etching process.

11. The method according to claim 2, wherein the first and second holes are formed such that first and second diameters of the first and second holes decrease as first and second levels of the first and second holes decrease, respectively.

12. A method of manufacturing a semiconductor device, comprising:
forming first and second electrodes in an insulating film over a semiconductor substrate, the first and second electrodes upwardly extending from the semiconductor substrate, the first and second electrodes having first and second upper portions protruding from an upper surface of the insulating film;
forming a support film which covers the upper surface of the insulating film and the first and second upper portions;
forming a mask over the support film, the mask overlapping at least partially the first and second electrodes in plan view;
patterning the support film using the mask so that a remaining portion of the support film connects the first and second upper portions; and
removing the insulating film while the remaining portion mechanically supports the first and second electrodes.

13. The method according to claim 12, further comprising:
after removing the insulating film, forming, while the remaining portion mechanically supports the first and second electrodes, a capacitor insulating film which covers the remaining portion of the support film and the first and second electrodes; and
forming a third electrode which covers the capacitor insulating film.

14. The method according to claim 12, further comprising:
after removing the insulating film, removing the remaining portion;
forming a capacitor insulating film which covers the first and second electrodes; and
forming a third electrode which covers the capacitor insulating film.

15. The method according to claim 14, wherein the remaining portion is removed by a plasma ashing process.

16. The method according to claim 12, wherein the insulating film is removed by a wet etching process.

17. A method of manufacturing a semiconductor device, comprising:
forming first and second holes in the insulating film;
forming first and second electrodes which cover first and second inner surfaces of the first and second holes, respectively;
selectively etching the insulating film so that first and second upper portions of the first and second electrodes protrude from an etched upper surface of the insulating film;
forming a support film comprising first to third portions, the first portion covering the etched upper surface, and the second and third portions filling upper spaces of the first and second holes covered by the first and second electrodes;
removing the second and third portions so that the first portion connects the first and second upper portions; and
removing the insulating film while the first portion mechanically supports the first and second electrodes.

18. The method according to claim 17, wherein removing the second and third portions comprises:
forming a mask over the support film, the mask covering the first portion; and
patterning the support film using the mask.

19. The method according to claim 17, wherein selectively etching the second insulating film is stopped when first and second vertical dimensions of the first and second upper portions become in the range of 1 percent to 15 percent of first and second depths of the first and second holes, respectively.

20. The method according to claim 17, further comprising:
removing the first portion by a plasma ashing process.
